(19) United States
(12) Patent Application Publication
(10) Pub. No.: US 2025/0006603 A1
(43) Pub. Date: Jan. 2, 2025

(54) FLIP CHIP AND PRE-MOLDED CLIP POWER MODULES

(71) Applicant: SEMICONDUCTOR COMPONENTS INDUSTRIES, LLC, Scottsdale, AZ (US)

(72) Inventors: Yong LIU, Cumberland Foreside, ME (US); Qing YANG, Shenzhen (CN)

(73) Assignee: SEMICONDUCTOR COMPONENTS INDUSTRIES, LLC, Scottsdale, AZ (US)

(21) Appl. No.: 18/344,292

(22) Filed: Jun. 29, 2023

(51) Int. Cl. H01L 23/495; H01L 21/56; H01L 23/00; H01L 23/31

(52) U.S. Cl. CPC H01L 23/49575; H01L 21/565; H01L 23/3107; H01L 23/49562; H01L 24/32; H01L 24/40; H01L 24/73; H01L 2224/32245; H01L 2224/40245; H01L 2224/73213; H01L 2924/13055; H01L 2924/13091; H01L 2924/3512

(57) ABSTRACT

Devices and methods are disclosed for high power inverter modules with enhanced thermal and mechanical performance, for use in electric vehicles. The disclosed devices feature enlarged clips that cover an entire die, to distribute mechanical forces, thus preventing die cracks for improved reliability. In these power modules, semiconductor dies are sandwiched between a three-layer direct bond metal (DBM) structure and the enlarged clip. A pre-molded clip assembly can be used that includes integrated metalliization to eliminate the need for external wire bonds. Alternatively, semiconductor dies can be inverted in a flip-chip configuration to face a modified DBM structure that integrates the metallization. Simulations of the disclosed power inverters indicate improved efficiency in dissipating heat.

### TECHNICAL FIELD

This description relates to assembling and packaging semiconductor device modules, semiconductor device assemblies, and semiconductor devices. More specifically, this description relates to semiconductor device modules with improved thermal performance and/or mechanical stress reduction.

### BACKGROUND

Semiconductor device assemblies, e.g., chip assemblies, that include power semiconductor devices can be implemented using multiple semiconductor dies, substrates (e.g., direct-bonded metal (DBM) substrates, die attach pads (DAPs)), electrical interconnections, and a molding compound. Power transistors can include, for example, insulated gate bipolar transistors (IGBTs), power metal-oxide-semiconductor field effect transistors (MOSFETs), and so forth. Fast recovery diodes (FRDs) may be used in conjunction with power transistors. Electrical interconnections within a high-power semiconductor device module can include, for example, bond wires, conductive spacers, and conductive clips. A polymer molding compound can serve as an encapsulant to protect components of the device assembly. Such high-power chip assemblies, encapsulated as semiconductor device modules, can be used in various applications, including electric vehicles (EVs), hybrid electric vehicles (HEVs), and industrial applications.

### SUMMARY

In some aspects, the techniques described herein relate to an apparatus, including: a semiconductor die; a direct bonded metal (DBM) structure coupled to a first side of the semiconductor die, the DBM structure providing single-sided cooling; a clip coupled to a second side of the semiconductor die; an integrated metal routing layer providing an electrical path to terminals of the semiconductor die; and a molding compound encapsulating the semiconductor die, the DBM structure and the clip, and the integrated metal routing layer to form a power module.

In some aspects, the techniques described herein relate to an apparatus, further including: a lead frame coupled to the integrated metal routing layer; and a mounting bracket coupled to the DBM structure.

In some aspects, the techniques described herein relate to an apparatus, wherein the semiconductor die is in a flip-chip configuration and the integrated metal routing layer is embedded in a top metal layer of the DBM structure.

In some aspects, the techniques described herein relate to an apparatus, wherein the integrated metal routing layer is embedded in a pre-molded clip assembly.

In some aspects, the techniques described herein relate to an apparatus, wherein the semiconductor die is a silicon carbide (SiC) chip.

In some aspects, the techniques described herein relate to an apparatus wherein the semiconductor die is an insulated gate bipolar transistor (IGBT) chip.

In some aspects, the techniques described herein relate to an apparatus, wherein the semiconductor die is attached to both the DBM structure and the clip by respective layers of sintered silver.

In some aspects, the techniques described herein relate to an apparatus, wherein the semiconductor die is attached to the DBM structure by a layer of sintered silver and to the clip by a layer of a lead-based solder.

In some aspects, the techniques described herein relate to an apparatus, wherein the lead-based solder includes lead selenium silver (PbSnAg).

In some aspects, the techniques described herein relate to an apparatus, wherein the power module is configured as an inverter for use in electric vehicles (EVs) and hybrid electric vehicles (HEVs).

In some aspects, the techniques described herein relate to an apparatus, wherein the DBM includes a Si3N4 ceramic layer.

In some aspects, the techniques described herein relate to a method, including: forming a pre-molded clip assembly, including a first encapsulant; attaching a semiconductor die to a direct bond metal (DBM) structure; attaching the pre-molded clip assembly to the semiconductor die; and encapsulating the semiconductor die, the pre-molded clip assembly, and the DBM structure in a second encapsulant to form a power module.

In some aspects, the techniques described herein relate to a method, wherein forming the pre-molded clip assembly includes forming an integrated metal routing layer therein.

In some aspects, the techniques described herein relate to a method, wherein forming the pre-molded clip assembly further includes forming a metal clip between the integrated metal routing layer and the semiconductor die.

In some aspects, the techniques described herein relate to a method, wherein forming the pre-molded clip assembly includes: sizing the integrated metal routing layer to be larger than the semiconductor die; and forming gate and source contacts to the semiconductor die in the integrated metal routing layer.

In some aspects, the techniques described herein relate to a method, wherein the first and second encapsulants are made of a similar epoxy molding compounds (EMCs).

In some aspects, the techniques described herein relate to a method, including: attaching a metal clip to cover a bottom surface of a semiconductor die; attaching the semiconductor die to a top metal layer of a direct bonded metal (DBM) structure; and encapsulating the semiconductor die, the metal clip, and the DBM structure in an epoxy molding compound to form a power module.

In some aspects, the techniques described herein relate to a method, wherein the top metal layer includes a central source contact and a gate contact that follows a perimeter of the top metal layer.

In some aspects, the techniques described herein relate to a method, wherein attaching the semiconductor die to the top metal layer of the DBM structure includes inverting the semiconductor die in a flip-chip process.

In some aspects, the techniques described herein relate to a method, wherein attaching the semiconductor die to the top metal layer of the DBM structure provides single-sided cooling thereto.

### BRIEF DESCRIPTION OF THE DRAWINGS

FIG. 1A is a perspective view of an integrated power module configured with a pre-molded clip, according to implementations of the present disclosure.

FIG. 1B is a side cross-sectional view of the integrated power module shown in FIG. 1A, along a cut plane A-A′, according to implementations of the present disclosure.

FIG. 1C is a magnified view of a central region of the integrated power module shown in FIG. 1B, according to implementations of the present disclosure.

FIG. 2A is a top side perspective view of a pre-molded clip assembly, according to implementations of the present disclosure.

FIG. 2B is a bottom side perspective view of the pre-molded clip assembly shown in FIG. 2A, according to implementations of the present disclosure.

FIG. 2C is a side cross-sectional view of the pre-molded clip assembly shown in FIG. 2B, along a cut plane B-B′ parallel to the x-z plane according to implementations of the present disclosure.

FIG. 3A is a perspective view of an integrated power module configured with a pre-molded clip, according to implementations of the present disclosure.

FIG. 3B is a side cross-sectional view of the integrated power module shown in FIG. 3A, along a cut plane A-A′, according to implementations of the present disclosure.

FIG. 3C is a magnified view of a central region of the integrated power module shown in FIG. 1B, according to implementations of the present disclosure.

FIG. 4A is a top side perspective view of a pre-molded clip assembly, according to implementations of the present disclosure.

FIG. 4B is a bottom side perspective view of the pre-molded clip assembly shown in FIG. 4A, according to implementations of the present disclosure.

FIG. 4C is a side cross-sectional view of the pre-molded clip assembly shown in FIG. 4B, along a cut plane B-B′ parallel to the x-z plane, according to implementations of the present disclosure.

FIG. 5 is a flow diagram illustrating a method of fabricating an integrated power module, according to an implementations of the present disclosure.

FIGS. 6A and 6B are plots of simulation results showing thermal resistance of integrated power modules, according to implementations of the present disclosure.

FIG. 7A is a perspective view of a flip-chip power module, according to implementations of the present disclosure.

FIG. 7B is a side cross-sectional view of the flip-chip power module shown in FIG. 7A, along a cut plane A-A′, parallel to the x-z plane, according to implementations of the present disclosure.

FIG. 7C is a magnified view of a central region of the flip-chip power module shown in FIG. 7B, according to implementations of the present disclosure.

FIG. 8 is a top plan view of integrated metallization for a flip-chip power module, according to implementations of the present disclosure.

FIG. 9A is a perspective view of a flip-chip power module, according to implementations of the present disclosure.

FIG. 9B is a side cross-sectional view of the flip-chip power module shown in FIG. 9A, along a cut plane A-A′, parallel to the x-z plane, according to implementations of the present disclosure.

FIG. 9C is a magnified view of a central region of the flip-chip power module shown in FIG. 9B, according to implementations of the present disclosure.

FIG. 10 is a top plan view of integrated metallization for a flip-chip power module, according to implementations of the present disclosure.

FIG. 11 is a flow diagram illustrating a method of fabricating a flip-chip power module, according to an implementations of the present disclosure.

FIGS. 12A and 12B are plots of simulation results showing thermal resistance of flip-chip power modules, according to implementations of the present disclosure.

FIGS. 13A and 13B are plots of simulation results showing thermal resistance of flip-chip power modules, according to implementations of the present disclosure.

Aspects of the present disclosure are best understood from the following detailed description when read with the accompanying figures. It is noted that, in accordance with common practice in the industry, various features are not necessarily drawn to scale. Dimensions of the various features may be arbitrarily increased or reduced for clarity of discussion. In the drawings, like reference symbols may indicate like and/or similar components (elements, structures, etc.) in different views. The drawings illustrate generally, by way of example, but not by way of limitation, various implementations discussed in the present disclosure. Reference symbols shown in one drawing may not be repeated for the same, and/or similar elements in related views. Reference symbols that are repeated in multiple drawings may not be specifically discussed with respect to each of those drawings but are provided for context between related views. Also, not all like elements in the drawings are specifically referenced with a reference symbol when multiple instances of an element are illustrated.

### DETAILED DESCRIPTION

Safety and reliability of high power electronic devices used in electric vehicles is important. Rigid metal clips that provide electrical connections and heat dissipation within a power inverter can cause cracks in the semiconductor dies to which they are attached. The cracks can arise due to differential heating and/or differential mechanical forces on portions of the dies that are in contact with the clips. Such conditions may arise during high temperature or high frequency operation when the power density in the clips increases. In addition, wire bonds used to access high power devices on semiconductor chips are inherently vulnerable to damage or breakage and consequently, can cause reliability failures. These concerns are particularly significant for high power modules e.g., modules operating at 650V, that carry large currents, e.g., 200A, and dissipate a significant amount of heat. These power inverters can include expensive materials such as silicon carbide (SiC), high tech ceramics made of silicon nitride (Si₃N₄), and direct bond metal (DBM) structures, e.g., direct bond copper (DBC) structures. When such high power modules are manufactured in large volume, yield and reliability improvements can add up to a substantial saving, in the millions of dollars.

This disclosure relates to implementations of power modules that feature enlarged clips that cover an entire die instead of a small portion of the die, to avoid hot spots. The enlarged clips are bonded to the die to distribute mechanical forces throughout the entire area of the die to prevent die cracks. In these power modules, semiconductor dies are sandwiched between a three-layer DBM structure and the enlarged clip.

In some implementations, the enlarged clip is in the form of a pre-molded clip assembly that includes integrated metalliization to eliminate the need for external wire bonds. The pre-molded clip assembly thus provides a modular solution for electrical connections to the semiconductor dies.

In some implementations, the semiconductor dies are inverted in an upside-down “flip-chip “configuration so that terminals of the semiconductor devices face a DBM structure. In the flip-chip configuration, metallization is integrated into a top layer of the DBM instead of being integrated into a pre-molded clip assembly. In the flip-chip configuration, the enlarged clip is attached to the upward-facing backside of the die.

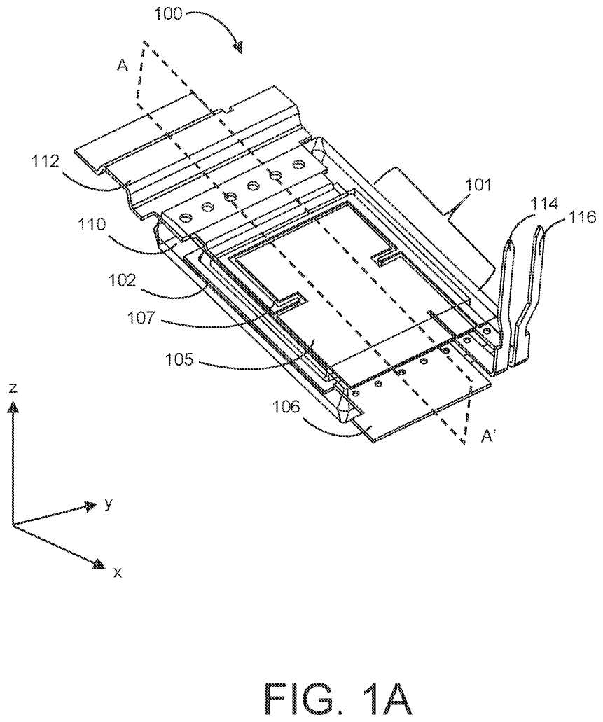

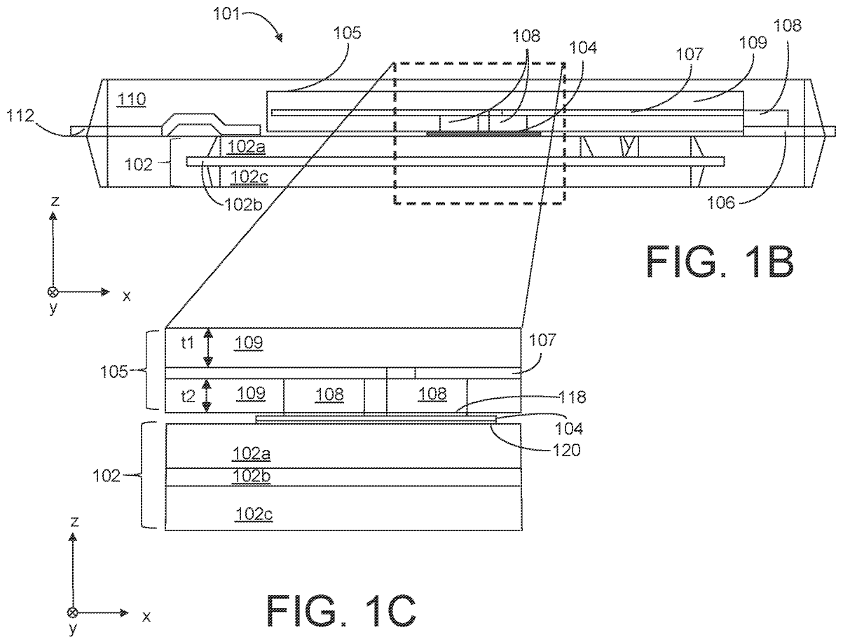

FIGS. 1A, 1B, and 1C show different views of a power module implemented with two side-by-side semiconductor dies and a pre-molded clip assembly that includes integrated metallization.

FIG. 1A is a perspective view of a high-power semiconductor device module, or integrated power module 100, in accordance with a first implementation of the present disclosure. In some implementations, the integrated power module 100 includes a high-power semiconductor chip assembly, or integrated electronic power assembly 101. The integrated electronic power assembly 101 includes a single-sided direct bond metal (DBM) structure 102, a die attach pad (DAP) 102a, one or more electronic components, e.g., semiconductor dies, or chip assemblies, 104, and a pre-molded clip assembly 105. In some implementations, the integrated electronic power assembly 101 operates at high voltages and currents, e.g., at about 650 Volts and 200 Amps.

The integrated power module 100 further includes a power source pin 106, a power drain pin 112, and lead frame posts 114 and 116. In some implementations, the power source pin 106, the power drain pin 112, and the lead frame posts 114 and 116 can be cut or stamped from a thin, rolled sheet of metal, e.g., copper. The power drain pin 112 and the power source pin 106 provide mechanical and electrical coupling at either end of the integrated power module 100, while the lead frame posts 114 and 116 provide electrical coupling for the integrated power module 100. In particular, the lead frame posts 114 and 116 provide signal paths from the integrated electronic power assembly 101 to external connections, e.g., temperature sense and gate control connections, respectively. In some implementations, the lead frame post 114 serves as a temperature sense pin and the lead frame post 116 serves as a gate pin. In some implementations, the power drain pin 112 serves as a power pin to provide power to drain terminals of the chip assemblies 104, and the power source pin 106 provides power to source terminals of the chip assemblies 104.

The power drain pin 112 can be used to mount the integrated power module 100 to an external connection such as a bus bar (not shown). The power drain pin 112 can be directly mechanically coupled to the DAP 102a. The power drain pin 112 can be shaped to include one or more bends, to permit an exterior portion of the power drain pin 112 to be substantially co-planar with an exterior portion of the power source pin 106.

The integrated electronic power assembly 101 and portions of the power source pin 106 and the power drain pin 112 can be encapsulated by an encapsulant 110 to complete formation of the integrated power module 100. In some implementations, the encapsulant 110, e.g., a polymer material, can be an epoxy molding compound (EMC) that serves to seal and protect various components of the integrated electronic power assembly 101.

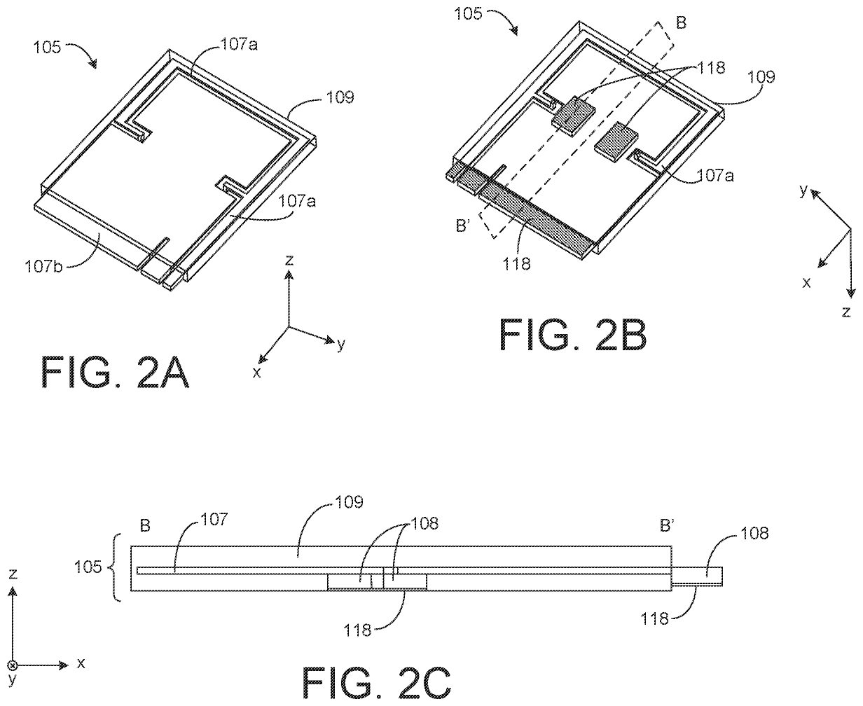

FIG. 1B is a side cross-sectional view of the integrated electronic power assembly 101 shown in FIG. 1A, along a cut plane A-A′, parallel to the x-z plane. FIG. 1B shows elements of the integrated electronic power assembly 101 that are included in the encapsulant 110, in accordance with the first implementation of the present disclosure. These include the DBM structure 102, the chip assemblies 104, and the pre-molded clip assembly 105, along with a portion of the power source pin 106 and a portion of the power drain pin 112. Details of the pre-molded clip assembly 105 are described further below with reference to FIG. 2C which features a magnified view of the pre-molded clip assembly 105.

The DBM structure 102 serves as a substrate and a heat sink for the chip assemblies 104. In some implementations, the DBM structure 102 can be a direct bond copper (DBC) type structure, a direct plating copper (DPC) type structure, or a direct bond aluminum (DBA) type structure. The DBM structure 102 may be referred to as a heat spreader that provides single-sided cooling of the chip assemblies 104 and the pre-molded clip assembly 105. In some implementations, the direct bond metal (DBM) structure 102 is designed as a three-layer DBM structure that includes an upper metal layer 102a and a lower metal layer 102c separated by a dielectric layer 102b. In some implementations, the DBM structure 102 has a total thickness in a range of about 0.5 mm to about 3.0 mm. The upper metal layer 102a serves as die attach pad for the chip assemblies 104. In some implementations, the dielectric layer 102b serves as a thermal mass disposed between the two outer metal layers to draw in and/or absorb heat. The dielectric layer 102b also provides electrical insulation between the upper metal layer 102a and the lower metal layer 102c of the DBM structure. In some implementations, the dielectric layer 102b can be a ceramic, e.g., silicon nitride (Si₃N₄) or aluminum oxide (Al₂O₃), Si₃N₄ being a significantly more expensive ceramic material than Al₂O₃. In some implementations, the dielectric layer 102b has a thickness in a range of about 0.30 mm to about 0.34 mm, and the upper metal layer 102a and the lower metal layer 102c each have a thickness in a range of about 0.6 mm to about 1.0 mm. In some implementations, the dielectric layer 102b can have a larger footprint that extends beyond the boundaries of the upper metal layer 102a and the lower metal layer 102c.

FIG. 1C is a magnified cross-sectional view of a central portion, shown as a dashed line box, of the integrated electronic power assembly 101 shown in FIG. 1B, in accordance with the first implementation of the present disclosure. FIG. 1C shows the DBM structure 102, the chip assembly 104a, and an enlarged view of the components of the pre-molded clip assembly 105. The pre-molded clip assembly 105 includes a metal routing layer 107, one or more clips 108 (two shown), and an encapsulant 109. The pre-molded clip assembly 105 fully covers the chip assemblies 104 to prevent die cracking.

The metal routing layer 107 connects the chip assemblies 104 to the lead frame post 114 and to the power source pin 106. In some implementations, the metal routing layer 107 is a layer of copper (Cu), aluminum (Al), or AlCu alloy metallization having a thickness in a range of about 0.20 mm to about 0.24 mm.

The clips 108 couple the metal routing layer 107 to the chip assemblies 104 and to the power source pin 106. In some implementations, the chip assemblies 104 have a thickness in a range of about 0.08 mm to about 0.12 mm. The clips 108 provide mechanical and electrical connections to terminals of the semiconductor devices on board the chip assemblies 104. The clips 108 also serve to dissipate heat from the chip assemblies 104. In some implementations, the clips 108 can be made of copper or another conductive material, e.g., Al or AlCu, having a thickness in a range of about 0.4 mm to about 0.8 mm. In some implementations, the clips 108 can be separated by an insulating material. The clips 108 can provide separate connections to different terminals of a device within a chip assembly 104.

The encapsulant 109 can be an epoxy molding compound (EMC) similar to the encapsulant 110. In some implementations, the encapsulant 109 has a thickness above and below the metal routing layer 107 in a range of about 1.3 mm to about 1.7 mm, which defines the thickness of the pre-molded clip assembly 105 as a modular unit. In some implementations, a thickness t1 of the encapsulant 109 above a top surface of the metal routing layer 107 is similar to a thickness t2 of the encapsulant 109 below a bottom surface of the metal routing layer 107. In some implementations, the thickness t1 of the encapsulant 109 above the top surface of the metal routing layer 107 can be different from the thickness t2 of the encapsulant 109 below the metal routing layer 107. Additional details of the encapsulant 109 are shown and described further below with reference to FIG. 2C.

FIG. 1C further shows bonding layers that hold together the integrated electronic power assembly 101. In some implementations, the pre-molded clip assembly 105 can be attached to, e.g., mounted on, or coupled to, the chip assemblies 104 by a first bonding agent 118, e.g., a lead-based solder such as lead selenium silver (PbSnAg) adhesive having a thickness in a range of about 0.03 mm to about 0.20 mm. The chip assemblies 104 are attached to, e.g., mounted on, or coupled to, a top surface of the die attach pad 102a by a second bonding agent 120, e.g., a conductive epoxy, a solder, a silver (Ag) sintering material, and/or a conductive adhesive. In some implementations, the second bonding agent 120 also has a thickness in a range of about 0.03 mm to about 0.20 mm. The chip assemblies 104, along with the first bonding agent 118 and the second bonding agent 120, are disposed in a gap between the pre-molded clip assembly 105 and the DBM structure 102. The gap can have a thickness that is substantially equal to the sum of the thicknesses of the chip assemblies 104 and the first and second bonding agents 118 and 120, without intervening materials. Space around the chip assemblies 104 within the gap is filled with the encapsulant 110.

FIGS. 2A, 2B, and 2C show views of the pre-molded clip assembly 105 and, in particular, electrical connections to the clips 108 within the pre-molded clip assembly 105.

FIG. 2A is a top side perspective view of the pre-molded clip assembly 105, in accordance with the first implementation of the present disclosure. FIG. 2A shows the encapsulant 109 of the pre-molded clip assembly 105 and the layout of the metal routing layer 107, which is embedded in the pre-molded clip assembly 105. The metal routing layer 107 features a wrap-around gate contact 107a and a source contact 107b. In some implementations, the upper metal layer 102a is designed to be substantially linear, whereas the dielectric layer 102b is designed to be substantially planar. The wrap-around gate contact 107a is routed around a perimeter of the pre-molded clip assembly 105 to couple gate terminals of the chip assemblies 104 directly to the lead frame post 116; the source contact 107b is routed to couple source terminals of the chip assemblies 104 directly to the lead frame post 114. FIG. 2A further shows that the encapsulant 109 forms a sleeve around the metal routing layer 107, such that the encapsulant 109 encloses the metal routing layer 107 except at one end where the wrap-around gate contact 107a and the source contact 107b extend out to the power source pin 106 from within the encapsulant 109 to form connections with the power source pin 106 and lead frame posts 114 and 116.

FIG. 2B is a bottom side perspective view of the pre-molded clip assembly 105, in accordance with the first implementation of the present disclosure. FIG. 2B shows the encapsulant 109 of the pre-molded clip assembly 105, the layout of the metal routing layer 107, and the first bonding agent 118, which attaches the underside of the pre-molded clip assembly 105 to the chip assemblies 104a and 104b (not shown), and to the power source pin 106. The first bonding agent 118 forms a pair of connections, e.g., soldered connections, between the integrated metallization, e.g., the metal routing layer 107 and the clips 108, and the chip assemblies 104 in the center of the pre-molded clip assembly 105. Although the chip assemblies 104a and 104b are not part of the pre-molded clip assembly 105, the footprints of the first bonding agent 118 shown in FIG. 2B indicate the positions of the chip assemblies 104a, on the left, and 104b on the right. The first bonding agent 118 also forms a connection, e.g., a soldered connection, to the power source pin 106 at a lower end of the pre-molded clip assembly 105.

FIG. 2C is a side cross-sectional view of the pre-molded clip assembly 105 along a cut plane B-B′ parallel to the x-z plane, in accordance with the first implementation of the present disclosure. FIG. 2C shows the encapsulant 109 of the pre-molded clip assembly 105, the metal routing layer 107, the clips 108 (three shown), and the first bonding agent 118. In some implementations, the encapsulant 109 wraps around five sides of the metal routing layer 107. In some implementations, the encapsulant 109 extends around one end of the metal routing layer 107, e.g., around the left end that is not coupled to a clip 108, as shown in FIG. 2C, so that the encapsulant 109 fully encloses one end of the metal routing layer 107.

Two clips 108 in the center of the pre-molded clip assembly 105 form connections, e.g., soldered connections, via the first bonding agent 118, between the metal routing layer 107 and respective terminals, e.g., gate and source terminals, of the chip assembly 104a. The clips 108 in the center of the pre-molded clip assembly 105 extend all the way through the encapsulant 109 below the metal routing layer 107 so that lower surfaces of the clips 108 are exposed and can connect to the chip assemblies 104 via the first bonding agent 118. The clip 108 at the right end of the pre-molded clip assembly 105 forms a connection, e.g., a soldered connection, via the first bonding agent 118, between the metal routing layer 107 and the power source pin 106.

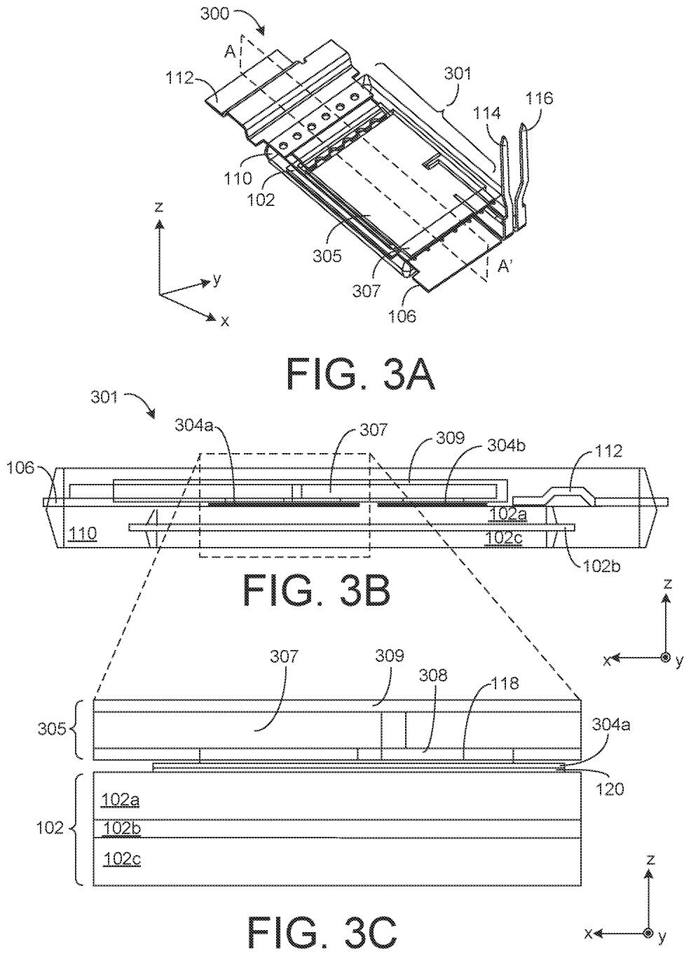

FIGS. 3A, 3B, and 3C show different views of a power module implemented with a diode semiconductor die, e.g., an FRD, and a transistor semiconductor die, e.g., an IGBT, in a vertical arrangement, and a pre-molded clip assembly that includes integrated metallization. The semiconductor dies and the metallization of the power module shown in FIGS. 3A, 3B, and 3C are different from those shown in FIGS. 1A, 1B, and 1C.

FIG. 3A is a perspective view of a high-power semiconductor device module, or integrated power module 300, in accordance with a second implementation of the present disclosure. In some implementations, the integrated power module 300 includes a high-power semiconductor chip assembly, or integrated electronic power assembly 301. The integrated electronic power assembly 301 includes the single-sided direct bond metal (DBM) structure 102, the die attach pad (DAP) 102a, one or more electronic components, e.g., semiconductor dies, or chip assemblies, 304, and a pre-molded clip assembly 305. In some implementations, the integrated electronic power assembly 301 operates at high voltages and currents, e.g., at about 650 Volts and 200 Amps.

The integrated power module 300 further includes the power source pin 106, the power drain pin 112, and lead frame posts 114 and 116. In some implementations, the power source pin 106, power drain pin 112, and lead frame posts 114 and 116 can be cut or stamped from a thin, rolled sheet of metal, e.g., copper. The power drain pin 112 and the power source pin 106 provide mechanical and electrical coupling at either end of the integrated power module 300, while the lead frame posts 114 and 116 provide electrical coupling for the integrated power module 300. In particular, the lead frame posts 114 and 116 provide signal paths from the integrated electronic power assembly 301 to external temperature sense and gate connections, respectively.

The power drain pin 112 can be used to mount the integrated power module 300 to an external device such as a bus bar (not shown). The power drain pin 112 can be directly mechanically coupled to the DAP 102a. The power drain pin 112 can be shaped to include one or more bends, to permit an exterior portion of the power drain pin 112 to be substantially co-planar with an exterior portion of the power source pin 106.

The integrated electronic power assembly 301 and portions of the power source pin 106 and the power drain pin 112 can be encapsulated by an encapsulant 110 to complete formation of the integrated power module 300. In some implementations, the encapsulant 110, e.g., a polymer material, can be an epoxy molding compound (EMC) that serves to seal and protect various components of the integrated electronic power assembly 301.

FIG. 3B is a side cross-sectional view of the integrated electronic power assembly 301 shown in FIG. 3A, along a cut plane A-A′, parallel to the x-z plane. FIG. 3B shows elements of the integrated electronic power assembly 301 that are included in the encapsulant 110, in accordance with the first implementation of the present disclosure. These include the DBM structure 102, the chip assemblies 304, and the pre-molded clip assembly 305, along with a portion of the power source pin 106 and a portion of the power drain pin 112.

The DBM structure 102 serves as a substrate and a heat sink for the chip assemblies 304. In some implementations, the DBM structure 102 can be a direct bond copper (DBC) type structure, a direct plating copper (DPC) type structure, or a direct bond aluminum (DBA) type structure. The DBM structure 102 may be referred to as a heat spreader that provides single-sided cooling of the chip assemblies 304 and the pre-molded clip assembly 305. In some implementations, the direct bond metal (DBM) structure 102 is designed as a three-layer DBM structure that includes an upper metal layer 102a and a lower metal layer 102c separated by a dielectric layer 102b. In some implementations, the DBM structure 102 has a total thickness in a range of about 0.5 mm to about 3.0 mm. The upper metal layer 102a serves as die attach pad for the chip assemblies 304. The dielectric layer 102b is as described above with respect to the integrated power module 100.

FIG. 3C is a magnified side cross-sectional view of a central portion, shown as a dashed line box, of the integrated electronic power assembly 301 shown in FIG. 3B, in accordance with the second implementation of the present disclosure. FIG. 3C shows the DBM structure 102, the chip assembly 304a, and an enlarged view of the components of the pre-molded clip assembly 305. The pre-molded clip assembly 305 includes a metal routing layer 307, clips 308 (two shown), and an encapsulant 309. The pre-molded clip assembly 305 fully covers the chip assemblies 304 to prevent die cracking.

The metal routing layer 307 connects the chip assemblies 304 to one or both of the lead frame posts 114, 116 and to the power source pin 106. In some implementations, the metal routing layer 307 is a layer of copper (Cu), aluminum (Al), or AlCu alloy metallization having a thickness in a range of about 0.56 mm to about 0.68 mm.

The clips 308 couple the metal routing layer 307 to the chip assemblies 304 and to the power source pin 106. In some implementations, the chip assemblies 304 have a thickness in a range of about 0.08 mm to about 0.12 mm. The clips 308 provide mechanical and electrical connections to terminals of the diode and transistor devices on board the chip assemblies 304. The clips 308 and the metal routing layer 307 also serve to dissipate heat from the chip assemblies 304. In some implementations, the clips 308 can be made of copper or another conductive material, e.g., Al or AlCu, having a thickness in a range of about 0.16 mm to about 0.20 mm. In some implementations, the clips 308 can be separated by an insulating material. The clips 308 can provide separate connections to different terminals of a device within a chip assembly 304.

The encapsulant 309 can be an epoxy molding compound (EMC) similar to the encapsulant 110. In some implementations, the encapsulant 309 has a thickness in a range of about 0.8 mm to about 1.2 mm, which defines the thickness of the pre-molded clip assembly 305 as a modular unit.

FIG. 3C further shows bonding layers that hold together the integrated electronic power assembly 301. In particular, the pre-molded clip assembly 305 can be attached to, e.g., mounted on, or coupled to, the chip assemblies 304 by the first bonding agent 118, e.g., a lead-based solder such as lead selenium silver (PbSnAg) adhesive having a thickness in a range of about 0.03 mm to about 0.20 mm. The chip assemblies 304 are attached to, e.g., mounted on, or coupled to, a top surface of the die attach pad 102a by the second bonding agent 120, e.g., an epoxy, a solder, a silver (Ag) sintering material, and/or an adhesive. In some implementations, the second bonding agent 120 also has a thickness in a range of about 0.03 mm to about 0.20 mm.

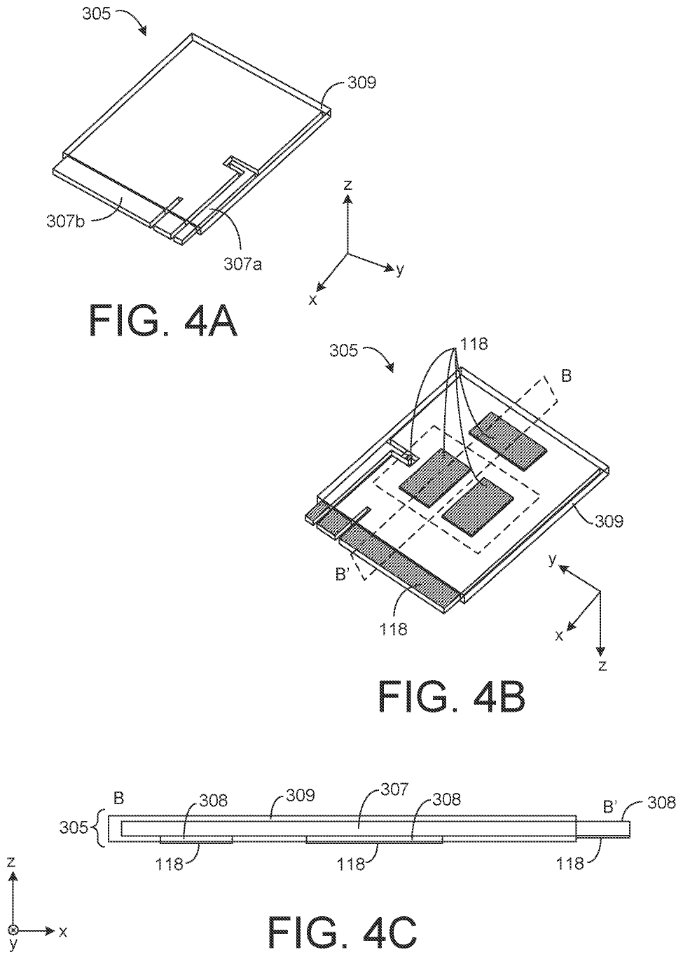

FIG. 4A is a top side perspective view of the pre-molded clip assembly 305, in accordance with the second implementation of the present disclosure. FIG. 4A shows the encapsulant 309 of the pre-molded clip assembly 305, and the layout of the metal routing layer 307, which is embedded in the pre-molded clip assembly 305. The layout of the metal routing layer 307 differs from the layout of the metal routing layer 107. The metal routing layer 307 features an L-shaped gate contact 307a and a large source contact 307b. The L-shaped gate contact 307a is routed to couple a gate terminal of the IGBT chip assembly 304b directly to the lead frame post 116; the source contact 307b is routed to couple source terminals of the chip assemblies 304 directly to the lead frame post 114.

FIG. 4B is a bottom side perspective view of the pre-molded clip assembly 305, in accordance with the second implementation of the present disclosure. FIG. 4B shows the encapsulant 309 of the pre-molded clip assembly 305, the layout of the metal routing layer 307, and coverage areas of the first bonding agent 118 (five shown), which attaches the pre-molded clip assembly 305 to the chip assemblies 304a and 304b (not shown), and to the power source pin 106. The first bonding agent 118 forms four connections, e.g., soldered connections, to the chip assemblies 304a, and 304b. Although the chip assemblies 304 are not part of the pre-molded clip assembly 305, the footprints of the first bonding agent 118 shown in FIG. 4B indicate the positions of the chip assemblies 304. For example, the first bonding agent 118 makes a single connection with the FRD die, and three connections with the IGBT die, within the dashed line box in FIG. 4B-a connection to the gate terminal of the IGBT via the L-shaped gate contact 307a on the far left side, and two connections to the source terminal of the IGBT in the center Of the pre-molded clip assembly 305. The first bonding agent 118 also forms a connection, e.g., a soldered connection, to the power source pin 106 at a lower end of the pre-molded clip assembly 305.

FIG. 4C is a side cross-sectional view of the pre-molded clip assembly 305 shown in FIG. 4B, along a cut plane B-B′ parallel to the x-z plane, in accordance with the second implementation of the present disclosure. FIG. 4C shows the encapsulant 309 of the pre-molded clip assembly 305, the layout of the metal routing layer 307, the clips 308 (three shown), and the first bonding agent 118. Two clips 308 in the center of the pre-molded clip assembly 305 form connections, e.g., soldered connections, via the first bonding agent 118, between the metal routing layer 307 and the chip assembly 304a (FRD) on the left and the chip assembly 304b (iGBT) on the right. The clip 308 at the right end of the pre-molded clip assembly 305 forms a connection, e.g., a soldered connection, via the first bonding agent 118, between the metal routing layer 307 and the power source pin 106 (not shown).

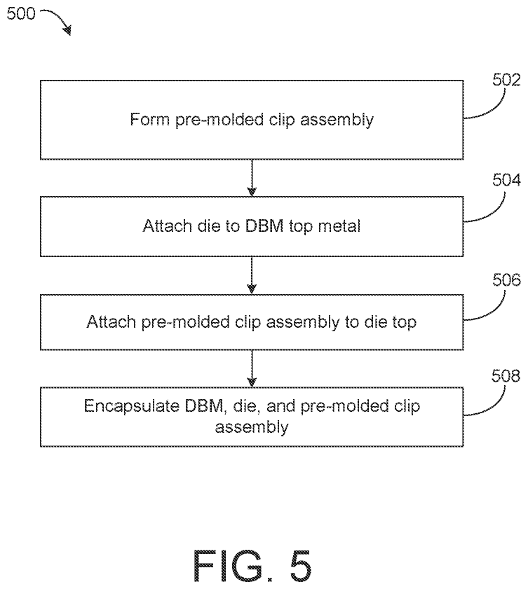

FIG. 5 is a flow chart illustrating a method 500 for fabricating a power module, e.g., the integrated power module 100 or the integrated power module 300, in accordance with some implementations of the present disclosure. Operations 502-508 of the method 500 can be carried out to form the integrated power modules 100 and 300, according to some implementations as described above with reference to FIGS. 1A, 1B, 1C, 2A, 2B, 2C, 3A, 3B, 3C, and 4A, 4B, and 4C. Operations of the method 500 can be performed in a different order, or not performed, depending on specific applications. It is noted that the method 500 may not produce a complete integrated power module 100. Accordingly, it is understood that additional processes can be provided before, during, or after method 500, and that some of these additional processes may be briefly described herein.

At 502, the method 500 includes forming a pre-molded clip assembly, e.g., the pre-molded clip assembly 105 or the pre-molded clip assembly 305, in accordance with an implementation of the present disclosure. The pre-molded clip assembly can be formed as two patterned metal layers: a first metal layer defining the clips, e.g., clips 108 or clips 308, followed by a second metal layer defining the metal routing layer, e.g., the metal routing layer 107 or the metal routing layer 307. The clips and the metal routing layer can then be encapsulated, e.g., in the encapsulant 109 or the encapsulant 309, by a process of injection molding, to complete the pre-molded clip assembly.

At 504, the method 500 includes attaching back sides of the chip assemblies 104 or the chip assemblies 304 to the DAP 102a, which is the top layer of the DBM structure 102, in accordance with an implementation of the present disclosure. Attaching the chip assemblies 104 and 304 can be accomplished using the second bonding agent 120. The power drain pin 112 can also be attached to the DAP 102a during operation 504.

At 506, the method 500 includes attaching the pre-molded clip assembly, e.g., the pre-molded clip assembly 105 or the pre-molded clip assembly 305, to top surfaces of the chip assemblies, e.g., the chip assemblies 104 or the chip assemblies 304, and to the power source pin 106 in accordance with an implementation of the present disclosure. The pre-molded clip assembly 105 can be attached to the chip assemblies 104 and the power source pin 106 using the first bonding agent 118 as shown in FIGS. 2B and 2C to form the integrated electronic power assembly 101. The pre-molded clip assembly 305 can be attached to the chip assemblies 304 and the power source pin 106 as shown in FIGS. 4B and 4C to form the integrated electronic power assembly 301.

At 508, the method 500 includes an encapsulation operation, in accordance with an implementation of the present disclosure. The integrated electronic power assembly, e.g., the integrated electronic power assembly 101 or the integrated electronic power assembly 301, can be surrounded by an encapsulant, e.g., an epoxy molding compound, to complete fabrication of a packaged integrated power module, e.g., the integrated power module 100 or the integrated power module 300. Encapsulation can be accomplished by, for example, a process of injection molding or a process of transfer molding.

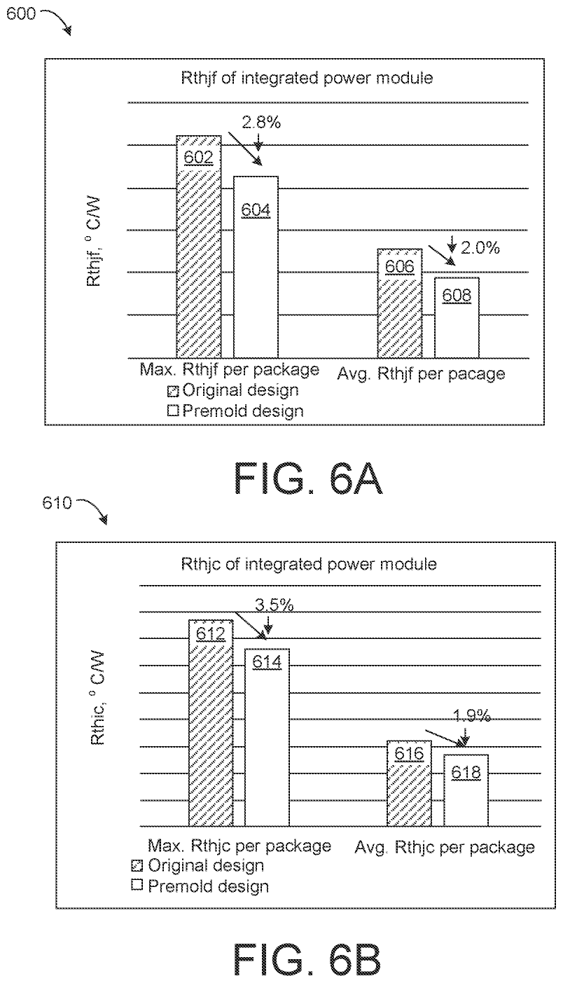

FIGS. 6A and 6B show simulation results of improvements in thermal performance associated with the pre-molded clip assemblies 105. FIG. 6A shows a plot 600 of computer simulation results for a junction-to-fluid thermal resistance parameter, (Rthjf), according to some implementations of the present disclosure. The units of Rthjf are in degrees C. per Watt, which represents heat radiated by power module during its operation. Thus, measuring Rthjf of the integrated power module 100 indicates efficiency of the heat sink provided by the pre-molded clip assembly 105 within the integrated power module 100. Lower thermal resistance is associated with faster heat transfer, provided by a more effective heat sink.

A first data set 602 is calculated as a representation of maximum thermal resistance within a power module that is not equipped with the pre-molded clip assembly 105. A second data set 604 is calculated as a representation of maximum thermal resistance within a packaged integrated power module 100 that is equipped with the pre-molded clip assembly 105. Improvement indicated by the first simulation data plot in FIG. 6A shows a 2.8% decrease in maximum thermal resistance Rthjf, attributable to the pre-molded clip assembly 105.

A third data set 606 is calculated as a representation of average thermal resistance within a power module that is not equipped with the pre-molded clip assembly 105. A fourth data set 608 is calculated as a representation of average thermal resistance within a packaged integrated power module 100 that is equipped with the pre-molded clip assembly 105. Improvement indicated by the second simulation data plot in FIG. 6A shows a 2.0% decrease in average thermal resistance Rthjf, attributable to the pre-molded clip assembly 105.

FIG. 6B shows a plot 610 of computer simulation results for a junction-to-case thermal resistance parameter, (Rthjc), according to some implementations of the present disclosure. The units of Rthjc are in degrees C. per Watt, which represents heat radiated by the integrated power module 100 during its operation. Thus, measuring Rthjc of the integrated power module 100 indicates efficiency of the heat sink provided by the pre-molded clip assembly 105 within the integrated power module 100. Lower thermal resistance is associated with faster heat transfer, provided by a more effective heat sink.

A first data set 612 is calculated as a representation of maximum thermal resistance within a power module that is not equipped with the pre-molded clip assembly 105. A second data set 614 is calculated as a representation of maximum thermal resistance within a packaged integrated power module 100 that is equipped with the pre-molded clip assembly 105. Improvement indicated by the first simulation data plot in FIG. 6B shows a 3.5% decrease in maximum thermal resistance Rthjc, attributable to the pre-molded clip assembly 105.

A third data set 616 is calculated as a representation of average thermal resistance within a power module that is not equipped with the pre-molded clip assembly 105. A fourth data set 618 is calculated as a representation of average thermal resistance within a packaged integrated power module 100 that is equipped with the pre-molded clip assembly 105. Improvement indicated by the second simulation data plot in FIG. 6B shows a 1.9% decrease in average thermal resistance Rthjc, attributable to the pre-molded clip assembly 105.

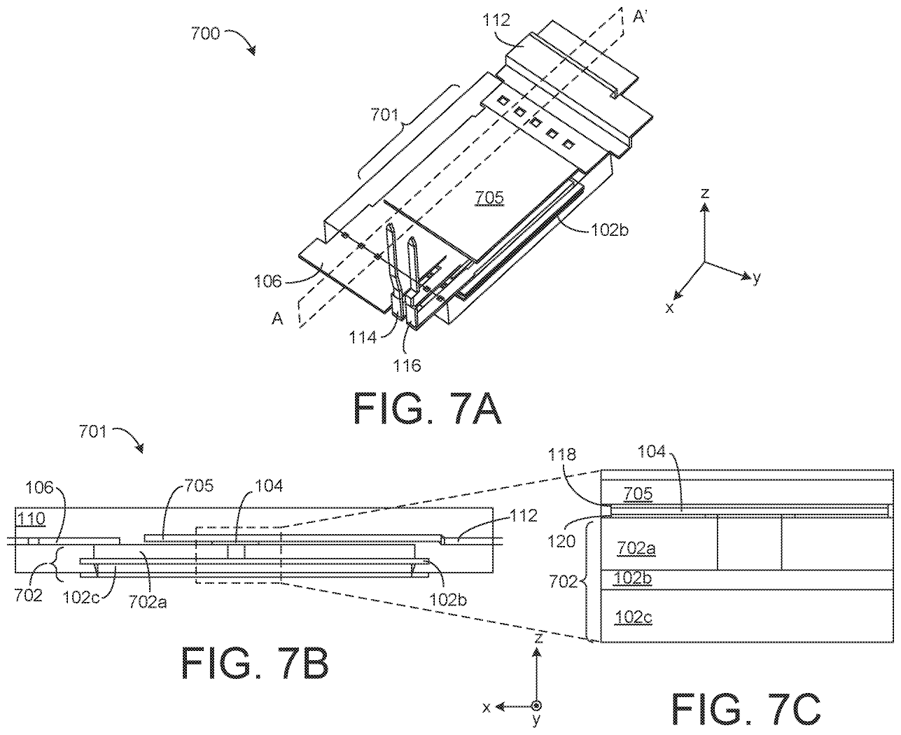

FIGS. 7A, 7B, and 7C show different views of a flip-chip power module 700 implemented with the chip assemblies 104 in a flip-chip configuration. The flip-chip power module 700 includes a drain clip that fully covers the chip assemblies 104 and a DAP having an upper metal layer that includes integrated metallization.

FIG. 7A is a perspective view of a high-power semiconductor device module, or flip-chip power module 700, in accordance with a third implementation of the present disclosure. In some implementations, the flip-chip power module 700 includes a high-power semiconductor chip assembly, or flip-chip electronic power assembly 701. The flip-chip electronic power assembly 701 includes a single-sided direct bond metal (DBM) structure 702, a die attach pad (DAP) 702a, one or more electronic components, e.g., semiconductor dies, or chip assemblies, 104, and a drain clip 705. In some implementations, the flip-chip electronic power assembly 701 operates at high voltages and currents, e.g., at about 650 Volts and 200 Amps.

The flip-chip power module 700 further includes the power source pin 106, the power drain pin 112, and the lead frame posts 114 and 116. In some implementations, the power source pin 106, power drain pin 112, and lead frame posts 114 and 116 can be cut or stamped from a thin, rolled sheet of metal, e.g., copper. The power drain pin 112 and the power source pin 106 provide mechanical coupling at either end of the flip-chip power module 700, while the lead frame posts 114 and 116 provide electrical coupling for the flip-chip power module 700. In particular, the lead frame posts 114 and 116 provide signal paths from the flip-chip electronic power assembly 701 to external temperature sense and gate connections.

The power drain pin 112 can be used to mount the flip-chip power module 700 to an external connection such as a bus bar (not shown). The power drain pin 112 can be directly mechanically coupled to the clip 705 that is attached to the back sides of the chip assemblies 104 by the first bonding agent 118. The power drain pin 112 can be shaped to include one or more bends, to permit an exterior portion of the power drain pin 112 to be substantially co-planar with an exterior portion of the power source pin 106.

The flip-chip electronic power assembly 701 and portions of the power source pin 106 and the power drain pin 112 can be encapsulated by an encapsulant 110 to complete formation of the flip-chip power module 700. In some implementations, the encapsulant 110, e.g., a polymer material, can be an epoxy molding compound (EMC) that serves to seal and protect various components of the flip-chip electronic power assembly 701.

FIG. 7B is a side cross-sectional view of the flip-chip electronic power assembly 701 shown in FIG. 7A, along a cut plane A-A′, parallel to the x-z plane. FIG. 7B shows elements of the flip-chip electronic power assembly 701 included in the encapsulant 110, in accordance with the third implementation of the present disclosure. These include the DBM structure 702, the chip assemblies 104, and the drain clip 705, along with a portion of the power source pin 106 and a portion of the power drain pin 112 that connects to the drain clip 705.

The DBM structure 702 serves as a substrate and a heat sink for the chip assemblies 104. In some implementations, the DBM structure 702 can be a direct bond copper (DBC) type structure, a direct plating copper (DPC) type structure, or a direct bond aluminum (DBA) type structure. The DBM structure 702 may be referred to as a heat spreader that provides single-sided cooling of the chip assemblies 104 and the drain clip 705. In some implementations, the direct bond metal (DBM) structure 702 is designed as a three-layer DBM structure that includes an upper metal layer 702a and a lower metal layer 102c separated by a dielectric layer 102b. In some implementations, the DBM structure 102 has a total thickness in a range of about 0.5 mm to about 3.0 mm.

The upper metal layer 702a serves as a DAP for the chip assemblies 104, and also serves as a metal routing layer 707 that provides electrical connections between the chip assemblies 104, the power source pin 106, and the lead frame posts 114 and 116. The DAP 702a provides mechanical and electrical connections to terminals of semiconductor devices on board the chip assemblies 104. The chip assemblies 104 are inverted so that the source and gate terminals of the semiconductor devices thereon are in flip contact with the DAP 702a.

In some implementations, the dielectric layer 102b serves as a thermal mass disposed between the two outer metal layers to draw in and absorb heat. The dielectric layer 102b also provides electrical insulation between the DAP 702a and the lower metal layer 102c of the DBM structure. In some implementations, the dielectric layer 102b can be a ceramic, e.g., silicon nitride (Si₃N₄) or aluminum oxide (Al₂O₃), Si₃N₄ being a significantly more expensive ceramic material than Al₂O₃. In some implementations, the dielectric layer 102b has a thickness in a range of about 0.30 mm to about 0.34 mm, and the upper and lower metal layers, 702a and 102c, respectively, each have a thickness in a range of about 0.6 mm to about 1.0 mm. In some implementations, the dielectric layer 102b can have a larger footprint that extends beyond the boundaries of the DAP 702a and the lower metal layer 102c.

FIG. 7C is a magnified cross-sectional view of a central portion, shown as a dashed line box, of the flip-chip electronic power assembly 701, in accordance with the third implementation of the present disclosure. FIG. 7C shows an enlarged view of the DBM structure 702, the chip assembly 104a, and the drain clip 705.

The drain clip 705 fully covers the inverted chip assemblies 104 to prevent die cracking. The drain clip 705 can also serve as an additional heat sink to dissipate heat from the chip assemblies 104. In some implementations, the chip assemblies 104 have a thickness in a range of about 0.08 mm to about 0.20 mm. In some implementations, the drain clip 705 can be made of copper or another conductive material, e.g., Al or AlCu, having a thickness in a range of about 0.36 mm to about 0.40 mm. The drain clip 705 can provide an electrical path to drain terminals of the semiconductor devices through the exposed substrates of chip assemblies 104.

FIG. 7C further shows bonding layers that hold together the flip-chip electronic power assembly 701. In particular, the drain clip 705 can be attached to, e.g., mounted on, or coupled to, the chip assemblies 104 by a first bonding agent 118, e.g., sintered silver (Ag) having a thickness in a range of about 0.03 mm to about 0.20 mm. The chip assemblies 104 are attached to, e.g., mounted on, or coupled to, a top surface of the die attach pad 702a by a second bonding agent 120, e.g., sintered silver (Ag). In some implementations, the second bonding agent 120 also has a thickness in a range of about 0.03 mm to about 0.20 mm.

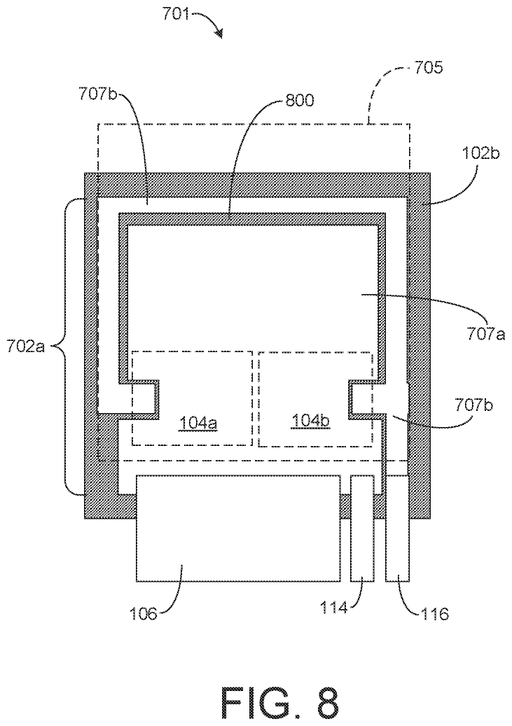

FIG. 8 is a top side plan view of the flip-chip electronic power assembly 701, in accordance with the third implementation of the present disclosure. FIG. 8 shows the dielectric layer 102b, the power source pin 106, the lead frame posts 114 and 116, the DAP 702a, a source contact 707a, and a wrap-around gate contact 707b of the metal routing layer 707. The dielectric layer 102b has a footprint that extends beyond the boundaries of the upper metal layer of the DBM structure 702, which is the DAP 702a.

FIG. 8 further indicates, in dashed line boxes, inverted positions that the flip chip assemblies 104 will occupy on top of the DAP 702a, as well as an outline of the drain clip 705 attached to the back side of the flip-chip assemblies 104 by the first bonding agent 118, e.g., by soldering or silver sintering. In some implementations, the chip assemblies 104 can include, for example, a first SiC transistor chip assembly 104a and a second SiC transistor chip assembly 104b. The chip assemblies 104 can be arranged side-by-side and can be mounted on the DAP 702a in a flip-chip configuration, in which both dies are upside down. In some implementations, other types of semiconductor dies can be used as one or more of the chip assemblies 104 in the flip-chip electronic power assembly 701. In some implementations, the term “chip assemblies 304” can refer to a single semiconductor die.

The chip assemblies 104 can be fabricated on various types of semiconductor substrates, e.g., semiconductor wafers, for example, silicon (Si), silicon carbide (SiC), gallium (Ga), gallium nitride (GaN), aluminum gallium nitride (AlGaN), gallium arsenide (GaAs), aluminum gallium arsenide (AlGaAs), indium phosphide (InP), glass substrates, sapphire substrates, and so on. In some implementations, the chip assemblies 104 can be fabricated on different substrates. For example, the chip assembly 104a can be fabricated on a silicon substrate, while the chip assembly 104b can be fabricated on a SiC substrate. In some implementations, the chip assemblies 104 are both fabricated on a SiC substrate.

FIG. 8 further shows the layout, relative sizes, and electrical connections, e.g., wiring, between the various components of the flip-chip electronic power assembly 701, in accordance with the third implementation of the present disclosure. A source contact 707a of the metal routing layer 707 that is patterned in the DAP 702a couples source terminals of the chip assembly 104a and the chip assembly 104b directly to the lead frame post 114. A wrap-around gate contact 707b in the metal routing layer 707, patterned in the DAP 702a, couples gate terminals of the chip assemblies 104 directly to the lead frame post 116. In some implementations, the wrap-around gate contact 707b follows a perimeter of the drain clip 705. The source contact 707a and the wrap-around gate contact 707b are insulated from one another by a gap 800 in the metal routing layer 707. Thus, by using the DAP 702a to integrate the metal routing layer 707, no wire bonds are needed to couple terminals of the chip assemblies 304 to the lead frame posts 114 and 116.

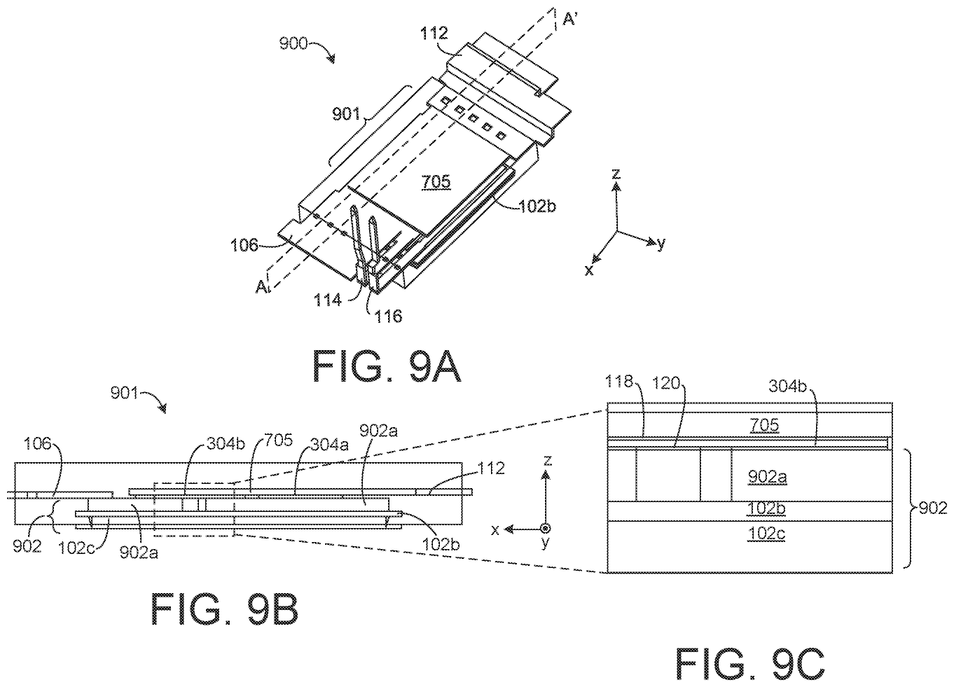

FIGS. 9A, 9B, and 9C show different views of a power module implemented with the chip assemblies 304 in a flip-chip configuration with a drain clip and a source DAP that includes integrated metallization.

FIG. 9A is a perspective view of a high-power semiconductor device module, or flip-chip power module 900, in accordance with a fourth implementation of the present disclosure. In some implementations, the flip-chip power module 900 includes a high-power semiconductor chip assembly, or flip-chip electronic power assembly 901. The flip-chip electronic power assembly 901 includes a single-sided direct bond metal (DBM) structure 902, a die attach pad (DAP) 902a, one or more electronic components, e.g., semiconductor dies, or chip assemblies, 304, and the drain clip 705. In some implementations, the flip-chip electronic power assembly 901 operates at high voltages and currents, e.g., at about 650 Volts and 200 Amps.

The flip-chip power module 900 further includes the power source pin 106, the power drain pin 112, and lead frame posts 114 and 116. In some implementations, the power source pin 106, power drain pin 112, and lead frame posts 114 and 116 can be cut or stamped from a thin, rolled sheet of metal, e.g., copper. The power drain pin 112 and the power source pin 106 provide both main electrical and mechanical coupling at either end of the flip-chip power module 900, while the lead frame posts 114 and 116 provide electrical coupling for the flip-chip power module 900. In particular, the lead frame posts 114 and 116 provide signal paths from the flip-chip electronic power assembly 901 to external temperature sense and gate control connections, respectively.

The power drain pin 112 can be used to mount the flip-chip power module 900 to an external heat sink (not shown). The power drain pin 112 can be directly mechanically coupled to the DAP 902a. The power drain pin 112 can be shaped to include one or more bends, to permit an exterior portion of the power drain pin 112 to be substantially co-planar with an exterior portion of the power source pin 106.

The flip-chip electronic power assembly 901 and portions of the power source pin 106 and the power drain pin 112 can be encapsulated by an encapsulant 110 to complete formation of the flip-chip power module 900. In some implementations, the encapsulant 110, e.g., a polymer material, can be an epoxy molding compound (EMC) that serves to seal and protect various components of the flip-chip electronic power assembly 901.

FIG. 9B is a side cross-sectional view of the flip-chip electronic power assembly 901 shown in FIG. 9A, along a cut plane A-A′, parallel to the x-z plane. FIG. 9B shows elements of the flip-chip electronic power assembly 901 included in the encapsulant 110, in accordance with the fourth implementation of the present disclosure. These include the DBM structure 902, the chip assemblies 304, and the drain clip 705, along with a portion of the power source pin 106 and a portion of the power drain pin 112.

The DBM structure 902 serves as a substrate and a heat sink for the chip assemblies 304. In some implementations, the DBM structure 902 can be a direct bond copper (DBC) type structure, a direct plating copper (DPC) type structure, or a direct bond aluminum (DBA) type structure. The DBM structure 902 may be referred to as a heat spreader that provides single-sided cooling of the chip assemblies 304 and the drain clip 705. In some implementations, the direct bond metal (DBM) structure 902 is designed as a three-layer DBM structure that includes an upper metal layer 902a and a lower metal layer 102c separated by a dielectric layer 102b. In some implementations, the DBM structure 102 has a total thickness in a range of about 0.5 mm to about 3.0 mm.

The upper metal layer 902a serves as a DAP for the chip assemblies 304, and also serves as a metal routing layer 907 that provides electrical connections between the chip assemblies 304, the power source pin 106, and the lead frame posts 114 and 116. The DAP 902a provides mechanical and electrical connections to terminals of semiconductor devices on board the chip assemblies 304. The chip assemblies 304 are inverted so that the terminals of the semiconductor devices thereon are in contact with the DAP 902a.

In some implementations, the dielectric layer 102b serves as a thermal mass disposed between the two outer metal layers to draw in and absorb heat. The dielectric layer 102b also provides electrical insulation between the DAP 902a and the lower metal layer 102c of the DBM structure. In some implementations, the dielectric layer 102b can be a ceramic, e.g., silicon nitride (Si₃N₄) or aluminum oxide (Al₂O₃), Si₃N₄ being a significantly more expensive ceramic material than Al₂O₃. In some implementations, the dielectric layer 102b has a thickness in a range of about 0.30 mm to about 0.34 mm, and the upper and lower metal layers, 902a and 102c, respectively, each have a thickness in a range of about 0.6 mm to about 1.0 mm. In some implementations, the dielectric layer 102b can have a larger footprint that extends beyond the boundaries of the DAP 902a and the lower metal layer 102c.

FIG. 9C is a magnified cross-sectional view of a central portion, shown as a dashed line box, of the flip-chip electronic power assembly 901, in accordance with the fourth implementation of the present disclosure. FIG. 9C shows an enlarged view of the DBM structure 902, the chip assembly 304a, and the drain clip 705.

The drain clip 705 fully covers the inverted chip assemblies 304 to prevent die cracking. The drain clip 705 can also serve as an additional heat sink to dissipate heat from the chip assemblies 304. In some implementations, the chip assemblies 304 have a thickness in a range of about 0.08 mm to about 0.20 mm. In some implementations, the drain clip 705 can be made of copper or another conductive material, e.g., Al or AlCu, having a thickness in a range of about 0.36 mm to about 0.40 mm. The drain clip 705 can provide an electrical path to drain terminals of the semiconductor devices through the exposed substrates of chip assemblies 304.

FIG. 9C further shows bonding layers that hold together the flip-chip electronic power assembly 901. In particular, the drain clip 705 can be attached to, e.g., mounted on, or coupled to, the chip assemblies 304 by a first bonding agent 118, e.g., sintered silver (Ag) having a thickness in a range of about 0.03 mm to about 0.20 mm. The chip assemblies 304 are attached to, e.g., mounted on, or coupled to, a top surface of the die attach pad 902a by a second bonding agent 120, e.g., sintered silver (Ag). In some implementations, the second bonding agent 120 also has a thickness in a range of about 0.03 mm to about 0.20 mm.

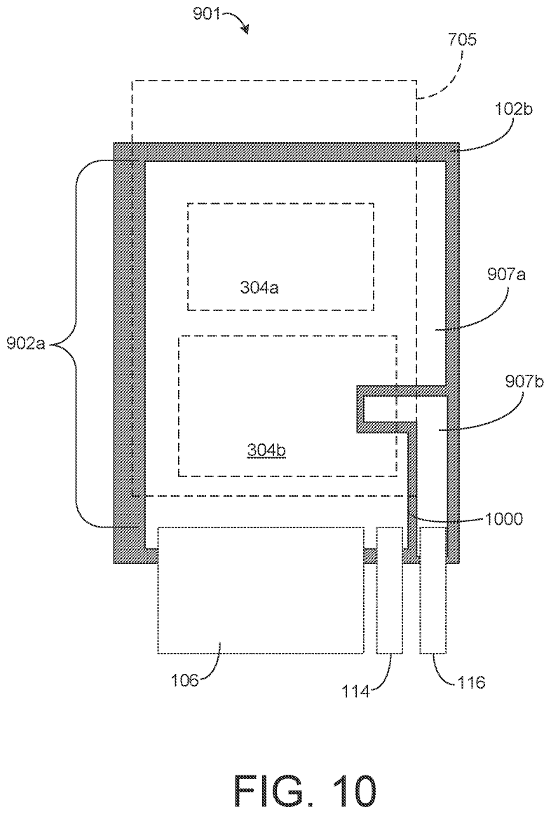

FIG. 10 is a top side plan view of the flip-chip electronic power assembly 901, in accordance with the fourth implementation of the present disclosure. FIG. 10 shows the dielectric layer 102b, the power source pin 106, the lead frame posts 114 and 116, the DAP 902a, a source contact 907a, and an L-shaped contact 907b of the metal routing layer 907. The dielectric layer 102b has a footprint that extends beyond the boundaries of the upper metal layer of the DBM structure 902, which is the DAP 902a.

FIG. 10 further indicates, in dashed line boxes, inverted positions that the chip assemblies 304 will occupy on top of the DAP 902a, as well as an outline of the drain clip 705.

In some implementations, the chip assemblies 304 can include, for example, an IGBT (transistor) chip assembly 304a and an FRD (diode) chip assembly 304b. The chip assemblies 304 can be arranged vertically and can be mounted on the DAP 902a in a flip-chip configuration, in which the IGBT and FRD dies are upside down. In some implementations, other types of semiconductor dies can be used as one or more of the chip assemblies 304 in the flip-chip electronic power assembly 901. In some implementations, the term “chip assemblies 304” can refer to a single semiconductor die.

The chip assemblies 304 can be fabricated on various types of semiconductor substrates, e.g., semiconductor wafers, for example, silicon (Si), silicon carbide (SiC), gallium (Ga), gallium nitride (GaN), aluminum gallium nitride (AlGaN), gallium arsenide (GaAs), aluminum gallium arsenide (AlGaAs), indium phosphide (InP), glass substrates, sapphire substrates, and so on. In some implementations, the chip assemblies 904 can be fabricated on different substrates. For example, an IGBT chip assembly 304a can be fabricated on a silicon substrate, while an FRD chip assembly 304b can be fabricated on a SiC substrate. In some implementations, the chip assemblies 304 are both fabricated on a SiC substrate.

FIG. 10 further shows the layout, relative sizes, and electrical connections, e.g., wiring, between the various components of the flip-chip electronic power assembly 901, in accordance with the fourth implementation of the present disclosure. A source contact 907a of the metal routing layer 907 that is patterned in the DAP 902a couples source terminals of the FRD chip assembly 304a and the IGBT chip assembly 304b directly to the power source pin 106 and the lead frame post 114. An L-shaped contact 907b in the metal routing layer 907 patterned in the DAP 902a couples a gate terminal of the IGBT chip assembly 304b directly to the lead frame post 116. The source contact 907a and the L-shaped contact 907b are insulated from one another by a gap 1000 in the metal routing layer 907. It is noted that the FRD chip assembly 304a, being a diode, does not have a gate contact. Thus, by using the DAP 902a to integrate the metal routing layer 907, no wire bonds are needed to couple terminals of the chip assemblies 304 to the power source pin 106, the lead frame post 114, or the lead frame post 116. Similarly, as shown in FIG. 9B, no wire bonds are needed to couple the power clip 705 to the power drain pin 112.

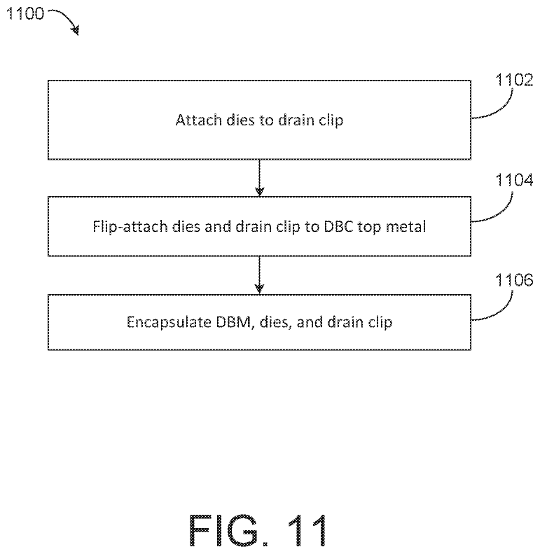

FIG. 11 is a flow chart illustrating a method 1100 for fabricating a flip-chip power module, e.g., the flip-chip power module 700 or the flip-chip power module 900, in accordance with some implementations of the present disclosure. Operations 1102-1106 of the method 1100 can be carried out to form the integrated power modules 700 and 900, according to some implementations as described above with reference to FIGS. 7A, 7B, 7C, 8, 9A, 9B, 9C, and 10. Operations of the method 1100 can be performed in a different order, or not performed, depending on specific applications. It is noted that the method 1100 may not produce a complete integrated power module. Accordingly, it is understood that additional processes can be provided before, during, or after method 1100, and that some of these additional processes may be briefly described herein.

At 1102, the method 1100 includes attaching the chip assemblies, e.g., the chip assemblies 104 or the chip assemblies 304 to a drain clip, e.g., the drain clip 705, in accordance with an implementation of the present disclosure. The drain clip 705 can contact drain terminals associated with devices on the chip assemblies 104 or the chip assemblies 304.

At 1104, the method 1100 includes flip-attaching front sides of the chip assemblies 104 to the DAP 702a, or the chip assemblies 304 to the DAP 902a, which is the top layer of the DBM structure. in accordance with an implementation of the present disclosure. Attaching the chip assemblies 104 and 304 can be accomplished using the second bonding agent 120, e.g., sintered silver. The power drain pin 112 can also be attached to the back side of the flip-chips through the drain clip 705. The power source pin 106 can be attached to the DAP, e.g., the DAP 702a or the DAP 902a, during operation 1104.

At 1106, the method 1100 includes an encapsulation operation, in accordance with an implementation of the present disclosure. The integrated electronic power assembly, e.g., the flip-chip electronic power assembly 701 or the flip-chip electronic power assembly 901, can be surrounded by an encapsulant, e.g., an epoxy molding compound, to complete fabrication of a packaged integrated power module, e.g., the flip-chip power module 700 or the flip-chip power module 900. Encapsulation can be accomplished by, for example, a process of injection molding or a process of transfer molding.

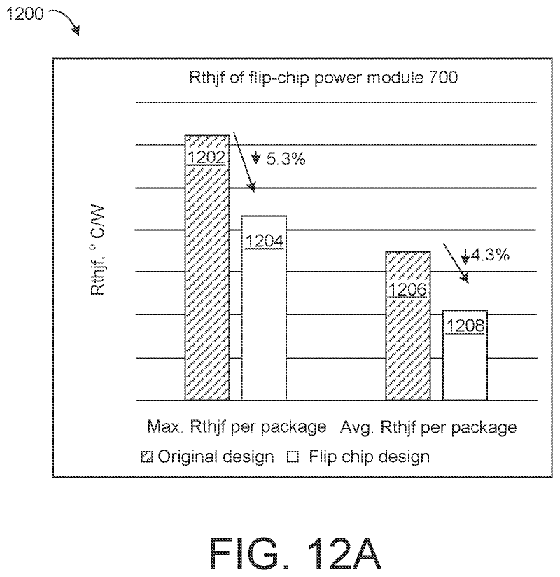

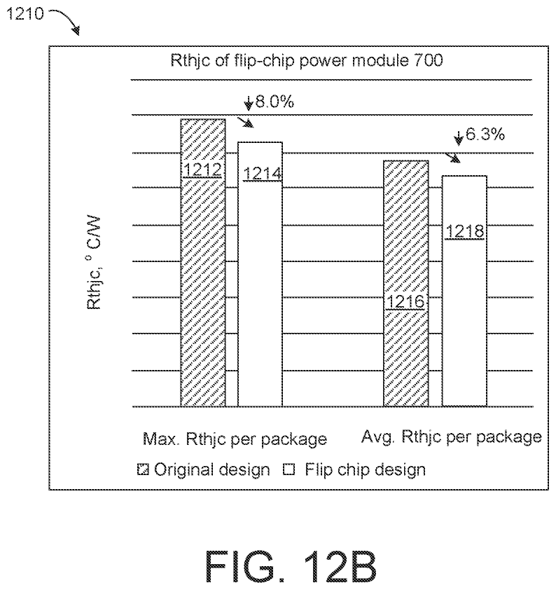

FIGS. 12A and 12B show simulation results of improvements in thermal performance of the flip-chip power module 700. FIG. 12A shows a plot 1200 of computer simulation results for a junction-to-fluid thermal resistance parameter, (Rthjf), according to some implementations of the present disclosure. The units of Rthjf are in degrees C. per Watt, which represents heat radiated by the flip-chip power module 700 during its operation. Thus, measuring

Rthjf of the flip-chip power module 700 indicates efficiency of the heat sink provided by the drain clip 705 and the DAP 702a within the flip-chip power module 700. Lower thermal resistance is associated with faster heat transfer, provided by a more effective heat sink.

A first data set 1202 is calculated as a representation of maximum thermal resistance within a power module that is not in a flip-chip configuration, including the drain clip 705 and the metal routing layer 707 in the DAP 702a. A second data set 1204 is calculated as a representation of maximum thermal resistance within a packaged flip-chip power module 700. Improvement indicated by the first simulation data plot in FIG. 12A shows a 5.3% decrease in maximum thermal resistance Rthjf, attributable to the flip-chip configuration.

A third data set 1206 is calculated as a representation of average thermal resistance within a power module that is not in the flip-chip configuration. A fourth data set 1208 is calculated as a representation of average thermal resistance within a packaged flip-chip power module 700. Improvement indicated by the second simulation data plot in FIG. 12A shows a 4.3% decrease in average thermal resistance Rthjf, attributable to the flip-chip configuration.

FIG. 12B shows a plot 1210 of computer simulation results for a junction-to-case thermal resistance parameter, (Rthjc), according to some implementations of the present disclosure. The units of Rthjc are in degrees C. per Watt, which represents heat radiated by the flip-chip power module 700 during its operation. Thus, measuring Rthjc of the flip-chip power module 700 indicates efficiency of heat transfer provided by the flip-chip configuration. Lower thermal resistance is associated with faster heat transfer, provided by a more effective heat sink.

A first data set 1212 is calculated as a representation of maximum thermal resistance within a power module that does not include a large clip, e.g., the drain clip 705. A second data set 1214 is calculated as a representation of maximum thermal resistance within the packaged flip-chip power module 700 including the drain clip 705. Improvement indicated by the first simulation data plot in FIG. 12B shows an 8.0% decrease in maximum thermal resistance Rthjc, attributable to the flip-chip configuration featuring the drain clip 705.

A third data set 1216 is calculated as a representation of average thermal resistance within a power module that does not include a large clip, e.g., the drain clip 705. A fourth data set 1218 is calculated as a representation of average thermal resistance within a packaged flip-chip power module 700, including the drain clip 705. Improvement indicated by the second simulation data plot in FIG. 12B shows a 6.3% decrease in average thermal resistance Rthjc, attributable to the flip-chip configuration featuring the drain clip 705.

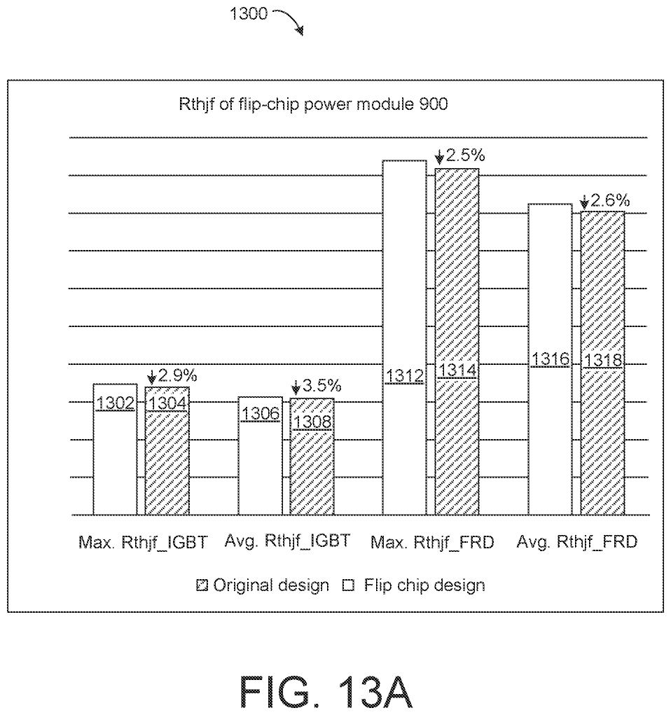

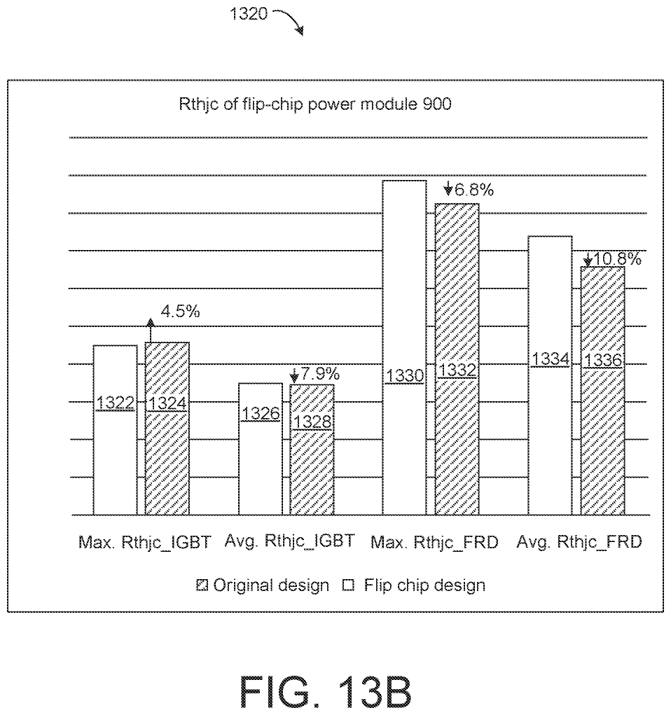

FIGS. 13A and 13B show simulation results of improvements in thermal performance associated with the flip-chip power module 900. FIG. 13A shows a plot 1300 of computer simulation results for a junction-to-fluid thermal resistance parameter, (Rthjf), according to some implementations of the present disclosure. The units of Rthjf are in degrees C. per Watt, which represents heat radiated by the flip-chip power module 900 during its operation. Thus, measuring Rthjf of the flip-chip power module 900 indicates efficiency of the heat sink provided by the drain clip 705 and the DAP 902a within the flip-chip power module 900.

A first data set 1302 is calculated as a representation of maximum thermal resistance within a power module in which an IGBT die is not in a flip-chip configuration. A second data set 1304 is calculated as a representation of maximum thermal resistance of an IGBT die in the flip-chip power module 900. Improvement indicated by the first simulation data plot in FIG. 13A shows a 2.9% decrease in maximum thermal resistance Rthjf, attributable to the flip-chip configuration.

A third data set 1306 is calculated as a representation of average thermal resistance within a power module in which an IGBT die is not in a flip-chip configuration. A fourth data set 1308 is calculated as a representation of average thermal resistance of an IGBT die in the flip-chip power module 900. Improvement indicated by the second simulation data plot in FIG. 13A shows a 3.5% decrease in average thermal resistance Rthjf, attributable to the flip-chip configuration.

A fifth data set 1312 is calculated as a representation of maximum thermal resistance within a power module in which an FRD die is not in a flip-chip configuration. A sixth data set 1314 is calculated as a representation of maximum thermal resistance of an FRD die in a flip-chip power module 900. Improvement indicated by the third simulation data plot in FIG. 13A shows a 2.5% decrease in maximum thermal resistance Rthjf, attributable to the flip-chip configuration.

A seventh data set 1316 is calculated as a representation of average thermal resistance within a power module in which an FRD die is not in a flip-chip configuration. An eighth data set 1318 is calculated as a representation of average thermal resistance of an FRD in a flip-chip power module 900. Improvement indicated by the fourth simulation data plot in FIG. 13A shows a 2.6% decrease in average thermal resistance Rthjf, attributable to the flip-chip configuration.

It is further noted that the simulation values of thermal resistance in data sets 1312, 1314, 1316, and 1318 shown in FIG. 13A for the FRD die are greater than the corresponding simulation values of thermal resistance in data sets 1302, 1304, 1306, and 1308 shown in FIG. 13A for the IGBT die

FIG. 13B shows a plot 1320 of computer simulation results for a junction-to-case thermal resistance parameter. (Rthjc), according to some implementations of the present disclosure. The units of Rthjc are in degrees C. per Watt, which represents heat radiated by the flip-chip power module 900 during its operation. Thus, measuring Rthjc of the flip-chip power module 900 indicates efficiency of the heat sink provided by the drain clip 705 and the DAP 902a within the flip-chip power module 900.

A first data set 1322 is calculated as a representation of maximum thermal resistance within a power module 900 in which an IGBT die is not in a flip-chip configuration. A second data set 1324 is calculated as a representation of maximum thermal resistance of an IGBT die in a flip-chip power module 900. Approximately equivalent performance is indicated by the first simulation data plot in FIG. 13B, which shows a 4.5% increase in a low level maximum thermal resistance Rthjc, attributable to the flip-chip configuration. This indicates a small increase in variability of the thermal resistance.

A third data set 1326 is calculated as a representation of average thermal resistance within a power module 900 in which an IGBT die is not in a flip-chip configuration. A fourth data set 1328 is calculated as a representation of average thermal resistance of an IGBT die in a flip-chip power module 900. Improvement indicated by the second simulation data plot in FIG. 13B shows a 7.9% decrease in average thermal resistance Rthjc, attributable to the flip-chip configuration.

A fifth data set 1330 is calculated as a representation of maximum thermal resistance within a power module in which an FRD die is not in a flip-chip configuration. A sixth data set 1332 is calculated as a representation of maximum thermal resistance of an FRD die in a flip-chip power module 900. Improvement indicated by the third simulation data plot in FIG. 13B shows a 6.8% decrease in maximum thermal resistance Rthjf, attributable to the flip-chip configuration.

A seventh data set 1334 is calculated as a representation of average thermal resistance within a power module in which an FRD die is not in a flip-chip configuration. An eighth data set 1336 is calculated as a representation of average thermal resistance of an FRD in a flip-chip power module 900. Improvement indicated by the fourth simulation data plot in FIG. 13B shows a 10.8% decrease in average thermal resistance Rthjf, attributable to the flip-chip configuration.

As described above, various implementations of power modules featuring integrated metallization and oversized clips can reduce thermal resistance to boost heat dissipation by as much as 10% . . . . At the same time, the integrated metallization also takes the place of wire bonds, for enhanced reliability. The metallization can be embedded in a modular pre-molded clip or in an upper layer of a single-sided DBM, for use with a flip-chip configuration. Different bonding materials can be used for the flip-chip configuration and the pre-molded clip implementation.

It will be understood that, in the foregoing description, when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, top, bottom, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor device processing techniques associated with semiconductor substrates including, but not limited to, for example, silicon (Si), silicon carbide (SiC), gallium arsenide (GaAs), gallium nitride (GaN), and/or so forth.

While certain features of the described implementations have been illustrated as described herein, many modifications, substitutions, changes, and equivalents will now occur to those skilled in the art. For instance, features illustrated with respect to one implementation can, where appropriate, also be included in other implementations. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

1. An apparatus, comprising:
a semiconductor die;
a direct bonded metal (DBM) structure coupled to a first side of the semiconductor die, the DBM structure configured to dissipate heat from the first side of the semiconductor die;
a pre-molded clip assembly coupled to a second side of the semiconductor die; and
a molding compound at least partially encapsulating the semiconductor die, the DBM structure and the pre-molded clip assembly, to form a power module.

2. The apparatus of claim 1, further comprising:
a lead frame coupled to the integrated metal routing layer; and
a mounting bracket coupled to the DBM structure.

3. The apparatus of claim 1, wherein the pre-molded clip assembly is an encapsulated modular unit.

4. The apparatus of claim 1, wherein the pre-molded clip assembly includes an integrated metal routing layer coupled to a terminal of the semiconductor die.

5. The apparatus of claim 1, wherein the semiconductor die is a silicon carbide (SiC) chip.

6. The apparatus of claim 1 wherein the semiconductor die is an insulated gate bipolar transistor (IGBT) chip.

7. The apparatus of claim 1, wherein the semiconductor die is attached to both the DBM structure and the clip by respective layers of sintered silver.

8. The apparatus of claim 1, wherein the semiconductor die is attached to the DBM structure by a layer of sintered silver and to the clip by a layer of a lead-based solder.

9. The apparatus of claim 8, wherein the lead-based solder includes lead selenium silver (PbSnAg).

10. The apparatus of claim 1, wherein the power module is configured as an inverter for use in electric vehicles (EVs) and hybrid electric vehicles (HEVs).

11. The apparatus of claim 1, wherein the DBM includes a Si₃N₄ ceramic layer.

12. A pre-molded clip assembly, comprising:
an encapsulant;
a metal routing layer centered within the encapsulant;
a first metal clip coupled to a lower surface of the metal routing layer and extending through the encapsulant; and
a second metal clip coupled to the lower surface of the metal routing layer and extending through the encapsulant; the second metal clip spaced apart from the first metal clip by an insulating material.

13. The pre-molded clip assembly of claim 17, wherein a first end of the metal routing layer is surrounded by the encapsulant, and an opposite end of the metal routing layer extends through the encapsulant to make contact with a first external element.

14. The pre-molded clip assembly of claim 17 wherein the first metal clip and the second metal clip are configured to make contact with portions of a second external element.

15. The pre-molded clip assembly of claim 19, wherein the second external element is a semiconductor die and the apparatus is sized to fit within an electronic power module.

16. A method, comprising:
forming a pre-molded clip assembly, including a first encapsulant;
attaching the pre-molded clip assembly to a semiconductor die;
attaching a semiconductor die to a direct bond metal (DBM) structure; and
encapsulating the semiconductor die, the pre-molded clip assembly, and the DBM structure in a second encapsulant to form a power module.

17. The method of claim 16, wherein forming the pre-molded clip assembly includes forming an integrated metal routing layer therein.

18. The method of claim 17, wherein forming the pre-molded clip assembly further includes forming a metal clip between the integrated metal routing layer and the semiconductor die.

19. The method of claim 17, wherein forming the pre-molded clip assembly includes:
sizing the integrated metal routing layer to be larger than the semiconductor die; and
forming gate and source contacts to the semiconductor die in the integrated metal routing layer.

20. The method of claim 17, wherein the first and second encapsulants are made of similar epoxy molding compounds (EMCs).
